(19) United States
(12) Patent Application Publication
(10) Pub. No.: US 2021/0289650 A1
(43) Pub. Date: Sep. 16, 2021

(54) HOUSING FOR A CONTROL DEVICE

(71) Applicant: KNORR-BREMSE SYSTEME FUER NUTZFAHRZEUGE GMBH, Muenchen (DE)

(72) Inventors: Elena Mueller, Nuernberg (DE); Norbert Behrendt, Stein (DE); Klaus Lechner, Pretzfeld (DE)

(21) Appl. No.: 16/331,206

(22) PCT Filed: Sep. 13, 2017
(86) PCT No.: PCT/EP2017/073009

§ 371 Date: Mar. 7, 2019

(30) Foreign Application Priority Data
Sep. 15, 2016 (DE) 10 2016 117 329.0

(51) Int. Cl. H05K 5/06; H05K 5/03; B60T 17/00

(52) U.S. Cl. CPC H05K 5/062; B60T 17/00; H05K 5/068; H05K 5/03

(57) ABSTRACT

A housing for a control device, including: a cover; a base plate; an elastic adhesive connection; in which the elastic adhesive connection provides a wet seal between the cover and the base plate. Also described are a related brake control device and a commercial vehicle.

### FIELD OF THE INVENTION

The present invention relates to a housing for a control device and in particular to sealing a housing of a brake control device by a wet seal.

### BACKGROUND INFORMATION

Control devices are to be reliably protected against environmental conditions in particular in commercial vehicles, while said control devices at the same time can be exposed to significant temperature variations. In order to ensure that neither water nor dirt nor dust can make its way into the control device, the control devices to date have been screw-fitted or riveted, wherein seal elements from rubber or plastics material have been utilized to achieve reliable sealing between the components of the housing.

However, the tightness of such housings, by virtue of vibrations or temperature variations, can often be guaranteed only to an insufficient extent over a comparatively long time period. In the case of many control devices such as, for example, brake control devices, there is moreover the requirement that said control devices also have to remain fully functional up to a specific depth (for example 50 cm or 1 m) under water, this not always being achieved by the existing control devices. There is therefore a demand for improved housings for control devices.

### SUMMARY OF THE INVENTION

The present invention is believed to solve at least some of the above-mentioned problems by a housing as described herein, a brake control device as described herein, and a commercial vehicle as described herein. The further descriptions herein relate to advantageous refinements of the subject matter as described herein.

The present invention relates to a housing for a control device. The housing comprises a cover, a base plate, and an elastic adhesive connection. The elastic adhesive connection forms a wet seal between the cover and the base plate. The wet seal can in particular be water-tight or air-tight, respectively.

In the case of further exemplary embodiments the cover comprises a rigid material, and the base plate at least partially forms a diaphragm so as to equalize a pressure differential between an environment and an interior of the housing by way of flexing of the base plate or by way of deformation of the latter.

In the case of further exemplary embodiments the cover comprises a groove having an adhesive compound, and the base plate comprises a protrusion, wherein the protrusion of the base plate protrudes into the adhesive compound so as to form the elastic adhesive connection between the cover and the base plate.

In the case of further exemplary embodiments the protrusion includes a holding arrangement so as to improve an adhesion of the elastic adhesive connection.

In the case of further exemplary embodiments the holding arrangement comprise at least one of the following: a further protrusion, at least one opening, a roughened surface region, barbs, an irregular surface structure.

In the case of further exemplary embodiments the elastic adhesive connection is configured in a fully circumferential manner along a circumference of the base plate.

The present invention also relates to a brake control device having a housing as has been described above. The invention moreover relates to a commercial vehicle having the brake control device. The control device can in principle be any control device, in particular also a brake control device, of an arbitrary vehicle.

The exemplary embodiments of the present invention will be better understood by way of the detailed description hereunder and the appended drawings of the various exemplary embodiments, said description and drawings however not being intended to be understood as limiting the disclosure to the specific embodiments but rather serving only for the purpose of explanation and understanding.

### BRIEF DESCRIPTION OF THE DRAWINGS

FIG. 1 shows a housing for a control device according to one exemplary embodiment of the present invention.

FIG. 2 shows further details of the housing according to further exemplary embodiments of the present invention.

### DETAILED DESCRIPTION

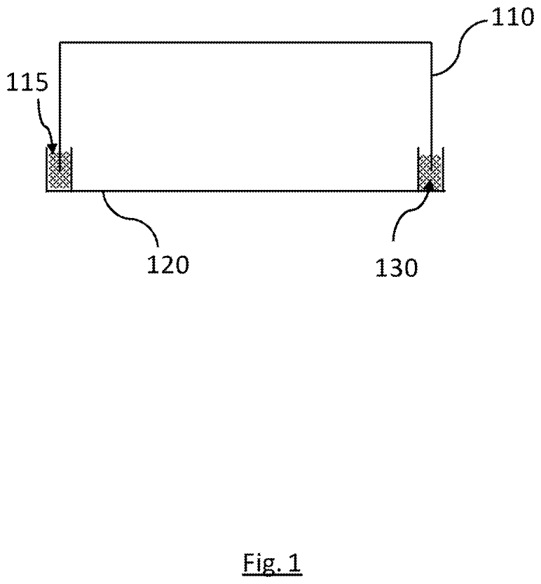

FIG. 1 shows a housing according to an exemplary embodiment of the present invention, said housing being suitable for a control device in a vehicle, in particular in a commercial vehicle. The housing comprises a cover 110, a base plate 120, and an adhesive connection 130 (for example an adhesive compound), so as to enable a tight connection between the cover 110 and the base plate 120. The cover 110 and the base plate 120 can in particular be connected to one another in an air-tight and water-tight manner. The control device can be any arbitrary control device, wherein a brake control device is in particular to be included. To this end, the base plate 120 in this exemplary embodiment comprises a groove 115 into which an end portion of the cover 110 is insertable so as to configure the elastic adhesive connection 130.

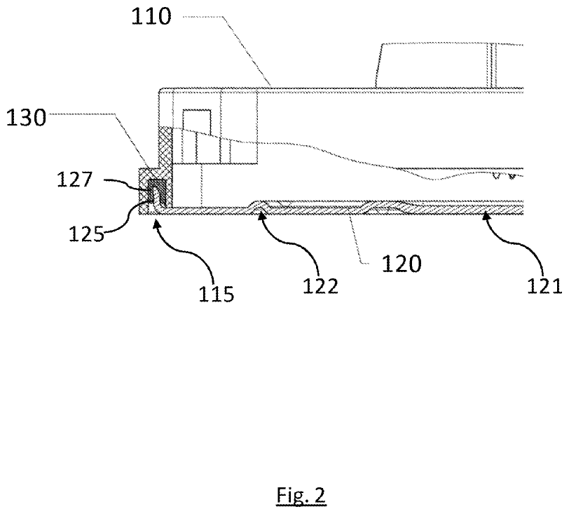

FIG. 2 shows further details of the housing according to further exemplary embodiments. The elastic adhesive connection 130 is again formed within a groove 115, wherein the groove now is part of the cover 110. The base plate 120 moreover comprises a protrusion 125 which protrudes into the groove 115 and is enclosed by the elastic adhesive connection 130 to the extent that a connection that is as water-tight as possible is achieved on account thereof.

The elastic adhesive connection 130 comprises, for example, an elastic adhesive which ensures adequate flexibility so as to maintain a permanently reliable adhesive connection, specifically even when the cover 110 and the base plate 120 move relative to one another on account of repeated thermal loadings, this often being the case in commercial vehicles (as a result of dissimilar coefficients of thermal expansion, for example).

The protrusion 125 in this exemplary embodiment moreover comprises holding arrangement 127 which are configured on an end of the protrusion 125, for example, and effect an improved retention of the base plate 120. The holding arrangement 127 can be configured in various ways. Bores, barbs, further protrusions, for example, are thus suitable for preventing an extraction of the base plate 120 from the elastic adhesive connection 130. The invention is however not limited to this specific shape. Rather, each irregular shape of the protrusion 125 can represent such a holding arrangement 127, as long as the latter is suitable for improving the retention of the base plate 120 in the elastic adhesive connection 130.

The base plate optionally comprises at least one portion which is configured as a diaphragm 121 so as to achieve a pressure equalization between an environment of the housing and a housing interior space by flexing or deformation of the diaphragm portion 121. To this end, the base plate 120 at least in portions can optionally be configured so as to be thinner, or to have a corresponding shape which facilitates flexing of the base plate 120. The base plate 120 can comprise a metal, for example, which at least in portions can be configured as a sheet metal so as to be able to equalize the pressure differentials mentioned. The base plate 120 can moreover comprise elevations 122 (that is to say that said base plate 120 is not mandatorily configured so as to be planar) which offer a supporting function for elements within the housing, on the one hand, but at the same time also can facilitate flexing of the diaphragm-type portion 121.

As opposed to exemplary embodiments of the present invention, conventional housings comprise separate pressure equalization elements. Said pressure equalization elements enable a gradual pressure equalization which may arise in the assembly, for example, to be established. The pressure equalization elements are however additional components which render the construction of the control devices more complicated and moreover can form an additional source of defects. Said pressure equalization elements, however, also complicate the production of the control devices. The present invention also relates in particular to housings which do not have any such separate pressure equalization elements.

One advantage of exemplary embodiments lies in the simple assembly. In particular, no screws or rivets are required, this enabling a space-saving assembly. The groove 115 can be adapted so as to correspond (for example in terms of the width, depth, a fully circumferential configuration, etc.) to the geometry of the base plate 120. Exemplary embodiments moreover achieve a reliable tightness between the cover 110 and the base plate 120 without tight tolerances having to be considered. In comparison to exemplary embodiments of the invention, tight tolerance dimensions have to be adhered to in the case of conventional screw or rivet connections, so as to guarantee a reliable fit of the separate seal, for example. A further advantage of exemplary embodiments lies in that the housing does not require any pressure equalization element since the elasticity, for example of the base plate 120, enables a pressure equalization (for example as a result of the temperature variation).

The present invention likewise relates to a brake control device having one of the housings described above. The present invention is also utilizable for other control devices within the vehicle (for example for an engine control device).

In the case of further exemplary embodiments, both the base plate 120 as well as the cover 110 are plasma-treated, for example subjected to plasma cleaning, prior to the adhesive bonding, so as to reliably ensure the retention and the tightness.

The features of the invention disclosed in the description, the claims, and the figures can be relevant individually as well as in any arbitrary combination to the implementation of the invention.

The LIST OF REFERENCE SIGNS is as follows:
110 Cover
115 Groove
120 Base plate
121 Diaphragm-type portion of the base plate
122 Elevations
125 Protrusion
127 Holding center
130 Elastic adhesive connection

1-8. (canceled)

9. A housing for a control device, comprising:
a cover;
a base plate;
an elastic adhesive connection;
wherein the elastic adhesive connection provides a wet seal between the cover and the base plate.

10. The housing of claim 9, wherein the cover has a rigid material, and the base plate at least partially forms a diaphragm so as to equalize a pressure differential between an environment and an interior of the housing by way of flexing of the base plate.

11. The housing of claim 9, wherein the cover has a groove having an adhesive compound, and the base plate has a protrusion, and wherein the protrusion of the base plate protrudes into the adhesive compound so as to form the elastic adhesive connection between the cover and the base plate.

12. The housing of claim 11, wherein the protrusion includes a holding arrangement so as to improve an adhesion of the elastic adhesive connection.

13. The housing of claim 12, wherein the holding arrangement includes at least one of the following: a further protrusion, an opening, a roughened surface region, a barb, and/or an irregular surface structure.

14. The housing of claim 9, wherein the elastic adhesive connection is configured in a fully circumferential manner along a circumference of the base plate.

15. A brake control device, comprising:
a housing for a control device, including:
a cover;
a base plate;
an elastic adhesive connection;
wherein the elastic adhesive connection provides a wet seal between the cover and the base plate.

16. A commercial vehicle, comprising:
a brake control device, including a housing for a control device, including:
a cover;
a base plate;
an elastic adhesive connection;
wherein the elastic adhesive connection provides a wet seal between the cover and the base plate.
